(19) United States
(12) Patent Application Publication
(10) Pub. No.: US 2025/0248251 A1
(43) Pub. Date: Jul. 31, 2025

(54) DISPLAY DEVICE

(71) Applicant: LG DISPLAY CO., LTD., Seoul (KR)

(72) Inventors: Youngjune GO, Paju-si (KR); Joohwan HWANG, Paju-si (KR); Wooseok NOH, Paju-si (KR); Hyejin KIM, Paju-si (KR)

(73) Assignee: LG DISPLAY CO., LTD., Seoul (KR)

(21) Appl. No.: 19/002,109

(22) Filed: Dec. 26, 2024

(30) Foreign Application Priority Data
Jan. 31, 2024 (KR) 10-2024-0014754

(51) Int. Cl. H10K 59/131; G09G 3/3225; H10K 59/80

(52) U.S. Cl. CPC H10K 59/131; H10K 59/80522; H10K 59/873; G09G 3/3225; G09G 2300/0842; G09G 2354/00

(57) ABSTRACT

A display device can include a substrate including a plurality of data lines, a plurality of gate lines, and a plurality of subpixels arranged in a display area of the display panel; a planarization layer on the plurality of data lines, the plurality of gate lines, and the plurality of subpixels. Each subpixel includes an anode electrode, a light emitting layer, and a cathode electrode that are sequentially stacked, one of an auxiliary cathode electrode and an organic material layer on the cathode electrode, and a capping layer on the one of the auxiliary cathode electrode and the organic material layer on the cathode electrode.

### CROSS-REFERENCE TO RELATED APPLICATION

This application claims priority to Korean Patent Application No. 10-2024-0014754, filed in the Republic of Korea on Jan. 31, 2024, the entire contents of which is hereby expressly incorporated by reference into the present application.

### BACKGROUND

### Field

Embodiments of the disclosure relate to a display device.

### Discussion of the Related Art

As technology continues to improve with ongoing research and development, display devices that display images are becoming lighter and thinner. The display device can include a light emitting element layer that emits light on its own. As the display device slims down, a thickness of the light emitting element layer decreases, and accordingly, the optical characteristics of the display device can vary from those of a thicker display device.

Specifically, as the thickness of the light emitting element layer decreases, the light emitted from the inside of the light emitting element layer can spread over a wide range, so that the viewing angle of the thinner display device can be widened and the viewing angle luminance can increase.

However, as the thickness of the light emitting element layer decreases, the efficiency of extracting the light emitted from the inside of the thinner light emitting element layer to the outside of the light emitting element layer can decrease due to resonance based on micro-cavity, and can lead to deterioration of the light emitting efficiency of the thinner display device.

Accordingly, it is necessary to secure optical characteristics that enhance the light emitting efficiency of the thinner display device without deteriorating the viewing angle characteristics by appropriately adjusting the thickness of the light emitting element layer in the thinner display device.

### SUMMARY OF THE DISCLOSURE

Embodiments of the disclosure can provide a display device capable of enhancing light efficiency without deteriorating viewing angle characteristics.

According to embodiments of the disclosure, there can be provided a display device capable of enhancing light efficiency without deteriorating viewing angle characteristics.

According to embodiments of the disclosure, there can be provided a display device capable of enabling low-power consumption by enhancing the light efficiency of the display device without deterioration of viewing angle characteristics.

According to an embodiment of the disclosure, a display panel can include a substrate including a plurality of data lines, a plurality of gate lines, and a plurality of subpixels arranged in a display area of the display panel; a planarization layer on the plurality of data lines, the plurality of gate lines, and the plurality of subpixels, wherein each subpixel includes: an anode electrode, a light emitting layer, and a cathode electrode that are sequentially stacked, one of an auxiliary cathode electrode and an organic material layer on the cathode electrode, and a capping layer on the one of the auxiliary cathode electrode and the organic material layer on the cathode electrode.

Each subpixel includes a first emission area corresponding to the anode electrode, the light emitting layer, and the cathode electrode that are stacked; a first non-emission area encircling the first emission area; and a second emission area encircling the first non-emission area, and wherein the first non-emission area is interposed between the first emission area and the second emission area.

The first non-emission area has a lower luminance that those of the first emission area and the second emission area.

The auxiliary cathode electrode and the organic material layer are transparent.

The auxiliary cathode electrode includes at least one of indium tin oxide (ITO) and indium zinc oxide (IZO).

The plurality of subpixels include a first subpixel and a second subpixel, wherein the first subpixel includes the auxiliary cathode electrode on the cathode electrode, and the second subpixel includes the organic material layer on the cathode electrode, and

wherein a thickness of the auxiliary cathode electrode is different from a thickness of the organic material layer. The first subpixel includes the auxiliary cathode electrode

a flat portion of the cathode electrode, and the organic material layer on an inclined portion of the cathode electrode.

The first subpixel includes the auxiliary cathode electrode on a flat portion and an inclined portion of the cathode electrode.

The cathode electrode can extend from the first subpixel to the second subpixel.

The light emitting layer of the first subpixel emits a blue light, and the light emitting layer of the second subpixel emits a blue light or a green light.

A first emission area of the first subpixel is larger than a first emission area of the second subpixel.

The plurality of subpixels include a first subpixel and a second subpixel, and wherein the first subpixel and the second subpixel include the auxiliary cathode electrode on the cathode electrode.

The organic material layer is on inclined portions of the cathode electrode in the first subpixel and the second subpixel.

The display panel can include a transmissive area disposed adjacent to the first subpixel and the second subpixel, wherein the transmissive area has a higher transparency than the first subpixel and the second subpixel.

The organic material layer is on the transmissive area.

A display device can include the display panel of claim 1; and an encapsulation layer on the display panel.

According to embodiments of the disclosure, a display panel can include a first subpixel and a second subpixel on a substrate; a planarization layer on the first and second subpixels; and a bank layer on the planarization layer, wherein each of the first and second subpixels includes an anode electrode, a light emitting layer, and a cathode electrode that are sequentially stacked, wherein the first subpixel includes an auxiliary cathode electrode on the cathode electrode of the first subpixel, and the second subpixel includes an organic material layer on the cathode electrode of the second subpixel, and wherein a thickness of the auxiliary cathode electrode is different from a thickness of the organic material layer.

For the first subpixel, the anode electrode includes a flat portion parallel to the substrate and an inclined portion angled to the substrate, wherein, for the first subpixel, the cathode electrode includes a flat portion parallel to the substrate and an inclined portion angled to the substrate, and wherein the light emitting layer is on the flat portion of the anode electrode, and wherein the auxiliary cathode electrode is on the flat portion of the cathode electrode.

The first subpixel includes: a first emission area corresponding to the light emitting layer, a first non-emission area encircling the first emission area; and a second emission area encircling the first non-emission area, and wherein the first non-emission area is interposed between the first emission area and the second emission area.

The light emitting layer is on the flat portion of the anode electrode entirely, and extends on the inclined portion of the bank layer.

According to embodiments of the disclosure, a display panel can include a substrate including a plurality of subpixels arranged in a display area of the display panel; a planarization layer on substrate, wherein each subpixel includes: a first emission area, a second emission area surrounding the first emission area, a first non-emission area between the first emission area and the second emission area, and a second non-emission area surrounding the second emission area, wherein each subpixel further includes: an anode electrode extending from the second non-emission area to the first emission area, a light emission layer on the anode electrode and overlapping the first emission area, a cathode electrode on the light emission layer and extending from the second non-emission area to the first emission area, an organic layer on the cathode electrode and overlapping the first emission area, and an auxiliary cathode electrode on the cathode electrode and extending from the second non-emission area to the first non-emission area.

The display panel can include a capping layer on the auxiliary cathode electrode and the organic material layer, and extending from the second non-emission area to the first emission area.

The bank layer includes an open area, and the organic material layer is in the open area.

The auxiliary cathode electrode includes an open area, and the organic material layer is in the open area.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating an example of a structure of a display device and a circuit structure included in a subpixel according to embodiments of the disclosure;

FIG. 2 is a view illustrating an example of a planar structure of a display device according to embodiments of the disclosure;

FIG. 3 is a view illustrating an example of a cross-sectional structure of part I-I′ of FIG. 2;

FIG. 4 is an enlarged view of area A of FIG. 3;

FIG. 5 is a view illustrating another example of a planar structure of a display device according to embodiments of the disclosure;

FIG. 6 is a view illustrating another example of a cross-sectional structure of the display device of FIG. 4;

FIGS. 7 and 8 are views illustrating another example of a planar structure of a display device according to embodiments of the disclosure; and

FIG. 9 is a view illustrating an example of a cross-sectional structure of part II-II′ of FIG. 8.

FIG. 10 is an enlarged view of area A of FIG. 3 according to another embodiment of the disclosure.

FIG. 11 is an enlarged view of area A of FIG. 3 according to another embodiment of the disclosure.

FIG. 12 is a view illustrating an example of a planar structure of a display device according to embodiments of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

The term “made of” for an element can fully encompass the meaning of being completely formed of the element, or simply including the element.

Hereinafter, various embodiments of the disclosure are described in detail with reference to the accompanying drawings.

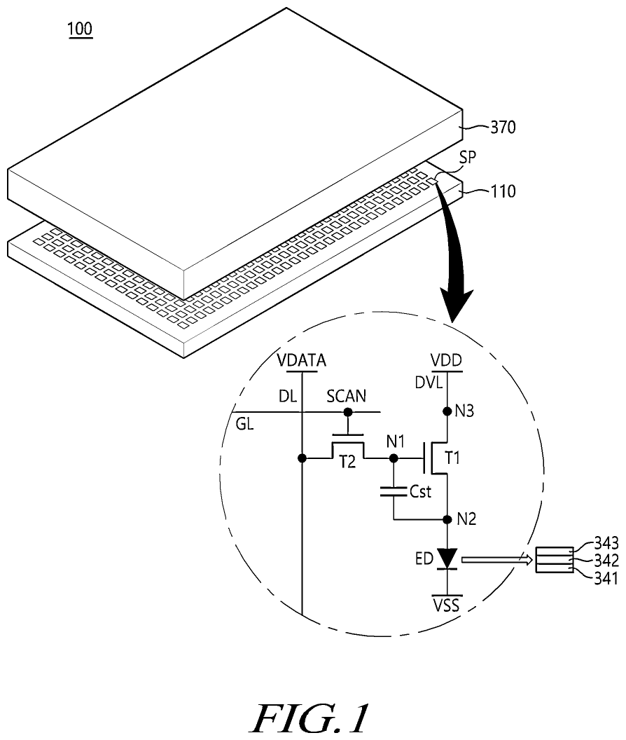

FIG. 1 is a view illustrating an example of a structure of a display device and a circuit structure included in a subpixel according to embodiments of the disclosure.

Referring to FIG. 1, a plurality of subpixels SP can be disposed on the display panel of the display device 100. All components of each display device or each display panel according to all embodiments of the present disclosure are operatively coupled and configured.

Each of the plurality of subpixels SP can include a light emitting element ED and a subpixel circuit unit configured to drive the light emitting element ED.

The subpixel circuit unit can include a driving transistor T1 for driving the light emitting element ED, a scan transistor T2 for transferring the data voltage VDATA to the first node N1 of the driving transistor T1, and a storage capacitor Cst for maintaining a constant voltage during one frame.

The driving transistor T1 can include the first node N1 to which the data voltage can be applied, a second node N2 electrically connected with the light emitting element ED, and a third node N3 to which a driving voltage VDD is applied from a driving voltage line DVL. The first node N1 in the driving transistor T1 can be a gate node, the second node N2 can be a source node or a drain node, and the third node N3 can be the drain node or the source node. For convenience of description, described below is an example in which the first node N1 in the driving transistor T1 is a gate node, the second node N2 is a source node, and the third node N3 is a drain node.

The light emitting element ED can include an anode electrode 341, a light emitting layer 342, and a cathode electrode 343. The anode electrode 341 can be a pixel electrode disposed in each subpixel SP and be electrically connected to the second node N2 of the driving transistor T1 of each subpixel SP. The cathode electrode 343 can be a common electrode commonly disposed in the plurality of subpixels SP, and a base voltage VSS can be applied thereto.

Conversely, the anode electrode 341 can be a common electrode, and the cathode electrode 343 can be a pixel electrode. Hereinafter, for convenience of description, it is assumed that the anode electrode 341 is a pixel electrode and the cathode electrode 343 is a common electrode.

The light emitting element ED can have one or more predetermined emission areas.

The light emitting element ED can be an organic light emitting diode (OLED), an inorganic light emitting diode, or a quantum dot light emitting element. When the light emitting element ED is an organic light emitting diode, the light emitting layer 342 in the light emitting element ED can include an organic material.

The scan transistor T2 can be on/off controlled by a scan signal SCAN, which is a gate signal, applied via the gate line GL and be electrically connected between the first node N1 of the driving transistor T1 and the data line DL.

The storage capacitor Cst can be electrically connected between the first node N1 and second node N2 of the driving transistor T1.

The subpixel circuit unit can have a 2T1C structure (T for transistor, and C for capacitor) which includes two transistors DT and ST and one capacitor Cst and, in some cases, each subpixel SP can further include one or more transistors or one or more capacitors.

The capacitor Cst can be an external capacitor intentionally designed to be outside the driving transistor T1, but not a parasite capacitor (e.g., Cgs or Cgd) which is an internal capacitor that can be present between the first node N1 and the second node N2 of the driving transistor T1. Each of the driving transistor T1 and the scan transistor T2 can be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer can be disposed on the display panel 110 to prevent penetration of external moisture or oxygen into the circuit elements (particularly, the light emitting element ED). The encapsulation layer Encap can be disposed to cover the light emitting elements ED.

Each of the plurality of subpixels SP can be disposed in a different form from that of FIG. 1 on the display panel 110 depending on the line structure.

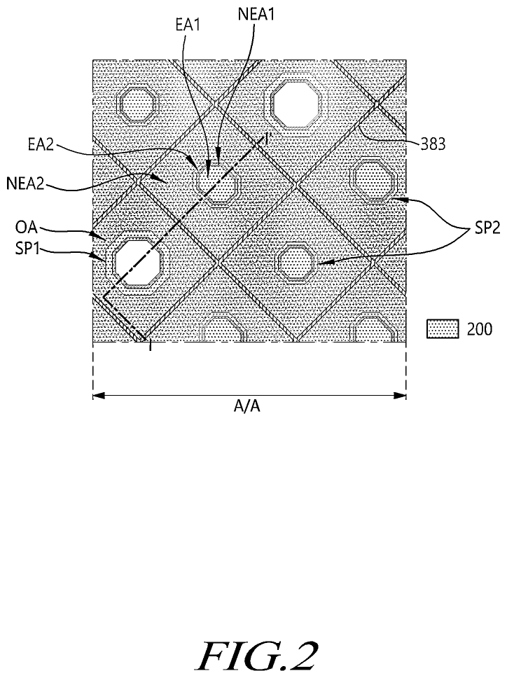

FIG. 2 is a view illustrating an example of a planar structure of a display device according to embodiments of the disclosure.

Referring to FIG. 2, a plurality of subpixels SP can be disposed in the display area A/A of the display panel 110. In various embodiments of the disclosure, structures discussed in terms of the display device also can be applicable to the display panel 110.

The plurality of subpixels SP can include a red subpixel SP, a green subpixel SP, and a blue subpixel SP.

Hereinafter, for convenience of description, the blue subpixel SP can be referred to as a first subpixel SP1, and the red subpixel SP or the green subpixel SP can be referred to as a second subpixel SP2.

A plurality of first subpixels SP1 and a plurality of second subpixels SP2 can be alternately disposed in the display area A/A.

Each of the first subpixel SP1 and the second subpixel SP2 can include a first emission area EA1, a first non-emission area NEA1, and a second emission area EA2.

The first emission area EA1 can refer to an area in which an anode electrode, a light emitting layer, and a cathode electrode are sequentially stacked, as is described below. Alternatively, it can refer to an area in which the bank layer is open.

The area of the first emission area EA1 of the first subpixel SP1 can be larger than the area of the first emission area EA1 of the second subpixel SP2.

The first emission area EA1 can be surrounded by the first non-emission area NEA1.

The first non-emission area NEA1 can be an area in a black state when the display panel is in an ON state. Alternatively, the first non-emission area NEA1 can be an area having lower luminance than the first emission area EA1 and the second emission area EA2.

The first non-emission area NEA1 can be surrounded by the second emission area EA2.

As the anode electrode has an inclined portion as is described below, the second emission area EA2 can be an area formed by the light reflected by the inclined portion of the anode electrode of the light emitted from the light emitting layer.

The area of the second emission area EA2 can be smaller than the area of the first emission area EA1. However, the disclosure is not limited thereto.

The second emission area EA2 can be distinguished from the first emission area EA1 by the first non-emission area NEA1.

As illustrated in FIG. 2, the first emission area EA1, the second emission area EA2, and the first non-emission area NEA1 can have an octagonal shape on a plane. However, the disclosure is not limited thereto, and the first emission area EA1, the second emission area EA2, and the first non-emission area NEA1 can have a circular shape, an elliptical shape, or a polygonal shape (e.g., a triangle, a square, or a hexagon) on a plane, or can be formed by a combination thereof.

The second emission area EA2 can be surrounded by the second non-emission area NEA2.

The second non-emission area NEA2 can mean an area between a plurality of subpixels SP. Specifically, it can be an area between the second emission area EA2 of the first subpixel SP1 and the second emission area EA2 of the second subpixel SP2.

As illustrated in FIG. 2, an organic material layer 200 can be disposed in the display area A/A.

The organic material layer 200 can be formed of a transparent material, and can be formed of a carbon organic material such as 3-(biphenyl-4-yl)-5-(4-tertbutylphenyl)-4-phenyl-4H-1, 2, 4-triazole (TAZ). However, the disclosure is not limited thereto. For example, other materials with hole transport property can be used.

The organic material layer 200 can be disposed to overlap at least one subpixel SP. For example, the organic material layer 200 can overlap all of the first emission area EA1, the first non-emission area NEA1, and the second emission area EA2 of the second subpixel SP2. However, the disclosure is not limited thereto.

Further, the organic material layer 200 can overlap the second non-emission area NEA2.

The organic material layer 200 can overlap the second emission area EA2 and the first non-emission area NEA1 of the first subpixel SP1.

The organic material layer 200 can be disposed outside the first emission area EA1. In other words, as illustrated in FIG. 2, the organic material layer 200 can be disposed in an area other than the first emission area EA1 of the first subpixel SP1. However, the disclosure is not limited thereto, and the organic material layer 200 can partially overlap the first emission area EA1.

The touch sensor layer can include a touch electrode 383 as is described below.

The touch electrode 383 can be formed in a mesh type and can be disposed to overlap the display area A/A.

When the touch electrode 383 is formed in a mesh type, the subpixel SP can be positioned in an area in which the touch electrode 383 is not disposed. In other words, the touch electrode 383 can be positioned in the second non-emission area NEA2.

An area in which the touch electrode 383 is not disposed in the second non-emission area NEA2 can also be referred to as an opening area OA of the touch electrode 383.

A plurality of opening areas OA can be present in the display area A/A.

One subpixel SP can be positioned in the opening area OA of one touch electrode 383.

Specifically, the opening area OA of the touch electrode 383 can include the second emission area EA2, the first non-emission area NEA1, and the first emission area EA1 of the first subpixel SP1.

Meanwhile, since the organic material layer 200 can be disposed to overlap the first non-emission area NEA1 and the second emission area EA2 of the first subpixel SP1, the opening area OA of the touch electrode 383 can include an area in which the organic material layer 200 is open. In other words, the area of the opening area OA of the touch electrode 383 can be larger than the area of the area in which the organic material layer 200 is open.

Hereinafter, a cross-sectional structure of a display device including an organic material layer 200 and a touch sensor layer is described.

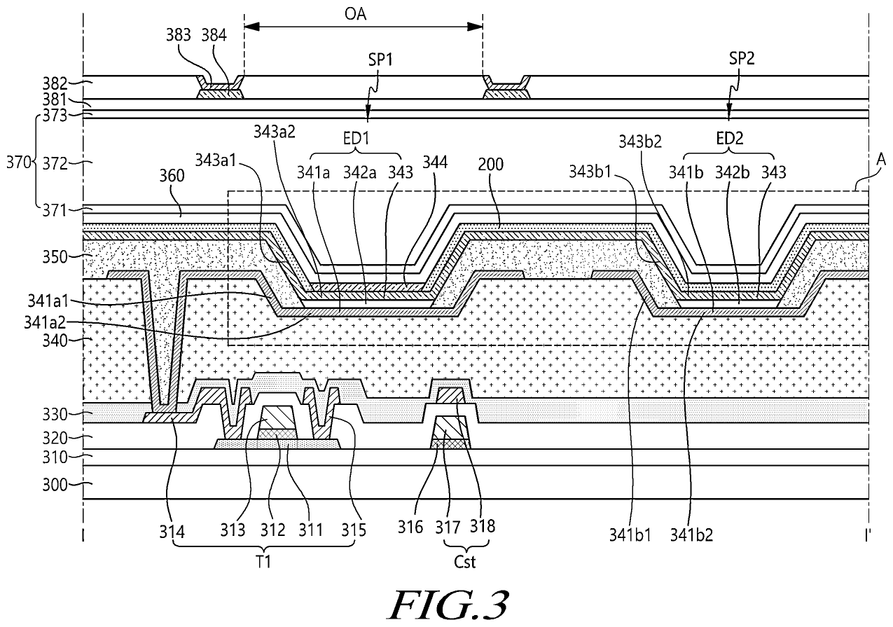

FIG. 3 is a view illustrating an example of a cross-sectional structure of part I-I′ of FIG. 2.

Referring to FIG. 3, a driving transistor Tl and a first light emitting element ED1 electrically connected to the driving transistor can be disposed on the substrate 300.

Specifically, the buffer layer 310 can be disposed on the substrate 300.

The substrate 300 can support various components of the display device. The substrate 300 can be formed of plastic such as polyimide, but is not limited thereto.

The buffer layer 310 can block various types of defects such as alkali components discharged from the substrate 300. The buffer layer 310 can be formed of a single layer of silicon nitride (SiNx) or silicon oxide (SiOx) or multiple layers thereof. But the disclosure is not limited thereto.

The active layer 311 of the driving transistor T1 and the first interlayer insulating layer 320 can be disposed on the buffer layer 310. The active layer 311 can be formed of an oxide, but is not limited thereto.

The active layer 311 can have a channel area in the area overlapping the gate electrode 313. The active layer 311 can include a source area and a drain area conductorized by a doping process on two opposite sides of the channel area.

An insulating layer 316 can be disposed on the buffer layer 310 in an area other than the area in which the driving transistor T1 is disposed. The insulating layer 316 can be formed of the same material as the gate insulating layer 312.

The gate insulating layer 312 can be disposed on the active layer 310. The gate insulating layer 312 can be formed of silicon nitride (SiNx) or silicon oxide (SiOx). But the disclosure is not limited thereto.

A gate electrode 313 can be disposed on the gate insulating layer 312.

A first interlayer insulating layer 320 can be disposed on the gate electrode 313 and the buffer layer 310. The first interlayer insulating layer 320 can be formed of silicon nitride (SiNx) or silicon oxide (SiOx). But the disclosure is not limited thereto.

The source electrode 314 and the drain electrode 315 of the transistor can be disposed on the first interlayer insulating layer 320. Each of the source electrode 314 and the drain electrode 315 can contact the active layer 310 through a hole formed in the first interlayer insulating layer 320.

The driving transistor T1 can be disposed on the substrate 300 in the above-described structure, but the structure of the driving transistor T1 is not limited thereto.

For example, the gate electrode 313 can be disposed on the substrate 300, the active layer 310 can be disposed on the gate electrode 313, the source electrode 314 can be disposed on the active layer 310 to overlap one end of the active layer 310, and the drain electrode 315 can be disposed to overlap the other end of the active layer 310. In other words, the driving transistor T1 can be formed in a bottom-gate structure. But the disclosure is not limited thereto.

The second interlayer insulating layer 330 can be disposed on the first interlayer insulating layer 320, the source electrode 314, and the drain electrode 315.

The second interlayer insulating layer 330 can be formed of the same material as the first interlayer insulating layer 330, but is not limited thereto.

A planarization layer 340 can be disposed on the second interlayer insulating layer 330.

The planarization layer 340 can be formed of at least one of organic insulating materials such as, but not limited to, benzocyclobutene (BCB), acryl resin, epoxy resin, phenolic resin, polyamide resin, or polyimide resin. The planarization layer 340 can be a single layer, but can be two or more layers considering the arrangement of the electrodes.

Meanwhile, a first capacitor electrode 317 can be disposed on the insulating layer 316 in an area other than the area in which the driving transistor T1 is disposed. The first capacitor electrode 317 can be formed of the same material as the gate electrode 313.

A second capacitor electrode 318 can be positioned on the first capacitor electrode 317. A first interlayer insulating layer 320 can be disposed between the first capacitor electrode 317 and the second capacitor electrode 318.

The first capacitor electrode 317 and the second capacitor electrode 318 can be formed of a single layer or multiple layers formed of any one of molybdenum (Mo), copper (Cu), titanium (Ti), aluminum (Al), chromium (Cr), gold (Au), nickel (Ni), neodymium (Nd), and tungsten (W), or an alloy thereof, but are not limited thereto.

The planarization layer 340 can have at least one concave area in an area overlapping the area in which the first subpixel SP1 is disposed and an area overlapping the area in which the second subpixel SP2 is disposed. Each concave area of the planarization layer 340 can include a flat surface and an inclined surface around the flat surface.

The flat surface included in the concave area of the planarization layer 340 can be parallel to the substrate 300. The inclined surface included in the concave area of the planarization layer 340 can be disposed around two opposite sides of the planarization surface to form a predetermined angle with the substrate 300. In other words, the inclined surface can be not parallel to the substrate 300.

The planarization layer 340 can include a hole around the concave area overlapping the first subpixel SP1.

The first anode electrode 341a and the second anode electrode 341b can be disposed on the planarization layer 340. The first anode electrode 341a can be an electrode disposed to overlap the first subpixel SP1, and the second anode electrode 341b can be an electrode disposed to overlap the second subpixel SP2.

The first anode electrode 341a and the second anode electrode 341b are electrodes that reflect light and can be formed of an opaque conductive material. For example, each anode electrode can be formed of at least one of silver (Ag), aluminum (Al), gold (Au), molybdenum (Mo), tungsten (W), chromium (Cr), or an alloy thereof. However, the disclosure is not limited thereto.

The first anode electrode 341a can include an inclined portion 341a1 and a flat portion 341a2. The second anode electrode 341b can include an inclined portion 341b1 and a flat portion 341b2.

The respective inclined portions 341a1 and 341b1 of the first and second anode electrodes 341a and 341b can refer to a portion disposed on the inclined surface included in a concave area of the planarization layer 340.

The respective flat portions 341a2 and 341b2 of the first and second anode electrodes 341a and 341b can refer to a portion disposed on the flat surface included in the concave area of the planarization layer 340.

Meanwhile, the first anode electrode 341a can be disposed to cover the sidewall of the planarization layer 340 in the hole formed in the planarization layer 340. The source electrode 314 of the transistor and the first anode electrode 341a of the first light emitting element ED1 can be electrically connected to each other through the hole formed in the planarization layer 340.

A bank layer 350 can be disposed on a portion of the planarization layer 340 and each of the anode electrodes 341a and 341b. The bank layer 350 can be formed of at least one of an inorganic insulating material such as silicon nitride (SiNx) or silicon oxide (SiOx) or an organic insulating material such as benzocyclobutene (BCB), acryl resin, epoxy resin, phenolic resin, polyamide resin, or polyimide resin, but is not limited thereto.

The bank layer 350 can have an opening area in an area overlapping the first subpixel SP1 and an area overlapping the second subpixel SP2.

The opening area of the bank layer 350 can be an area in which the bank layer 350 does not overlap the respective flat portions 341a2 and 341b2 of the first and second anode electrodes 341a and 341b. In other words, the bank layer 350 can cover a portion of the respective flat portions 341a2 and 341b2 of the first and second anode electrodes 341a and 341b.

The bank layer 350 can have an inclined surface in an area adjacent to two opposite ends of the opening area of the bank layer 350.

The angle formed by the inclined surface of the bank layer 350 with the substrate 300 can be the same as the angle formed by the inclined portions 341a1 and 341b1 of the first and second anode electrodes 341a and 341b with the substrate 300. However, the disclosure is not limited thereto.

The opening area of the bank layer 350 can be referred to as a first emission area EA1.

A first light emitting layer 342a can be disposed on the flat portion 341a2 of the first anode electrode 341a. A second light emitting layer 342b can be disposed on the flat portion 341a2 of the second anode electrode 341b.

Each of the first and second light emitting layers 342a and 342b can be a layer that emits light of a specific color, and can be one of a red light emitting layer, a green light emitting layer, and a blue light emitting layer. For example, the first light emitting layer 342a can be a blue light emitting layer, and the second light emitting layer 342b can be a green light emitting layer or a blue light emitting layer. However, the disclosure is not limited thereto.

A hole injection layer, a hole transport layer, an electron transport layer, and an electron injection layer can be further disposed above and below each of the first and second light emitting layers 342a and 342b.

A first cathode electrode 343 can be disposed on each of the first and second light emitting layers 342a and 342b and the bank layer 350.

The first cathode electrode 343 can overlap a plurality of subpixels SP including the first subpixel SP1 and the second subpixel SP2. In other words, as described above, the first cathode electrode 343 can be a common electrode commonly disposed in the plurality of subpixels SP.

The first cathode electrode 343 can include a first inclined portion 343a1, a first flat portion 343a2, a second inclined portion 343b1, and a second flat portion 343b2.

The first flat portion 343a2 of the first cathode electrode 343 can refer to a portion disposed on the first light emitting layer 342a, and the second flat portion 343b2 of the first cathode electrode 343 can refer to a portion disposed on the second light emitting layer 342b.

The first inclined portion 343a1 of the first cathode electrode 343 can refer to a portion disposed on the inclined surface of the bank layer 350, surrounding the first flat portion 343a2 of the first cathode electrode 343, and forming a predetermined angle with the substrate 300.

The second inclined portion 343b1 of the first cathode electrode 343 can refer to a portion disposed on the inclined surface of the bank layer 350, surrounding the second flat portion 343b2 of the first cathode electrode 343, and forming a predetermined angle with the substrate 300.

The angle formed by the first inclined portion 343a1 of the first cathode electrode 343 and the second inclined portion 343b1 of the first cathode electrode 343 with the substrate 300 can be the same as the angle formed by the inclined surface of the bank layer 350 with the substrate 300. However, the disclosure is not limited thereto.

The organic material layer 200 and the second cathode electrode 344 can be disposed on the first cathode electrode 343.

The organic material layer 200 can overlap the second subpixel SP2, can partially overlap the first subpixel SP1, and can be partially open in an area overlapping the first subpixel SP1.

The thickness of the organic material layer 200 can be larger than the thickness of the second cathode electrode 344. For example, the thickness of the organic material layer 200 can be 100A. However, the disclosure is not limited thereto.

The organic material layer 200 can be disposed on the first inclined portion 343a1 of the first cathode electrode 343 in an area overlapping the first subpixel SP1. The organic material layer 200 can at least partially cover the first inclined portion 343a1 of the first cathode electrode 343.

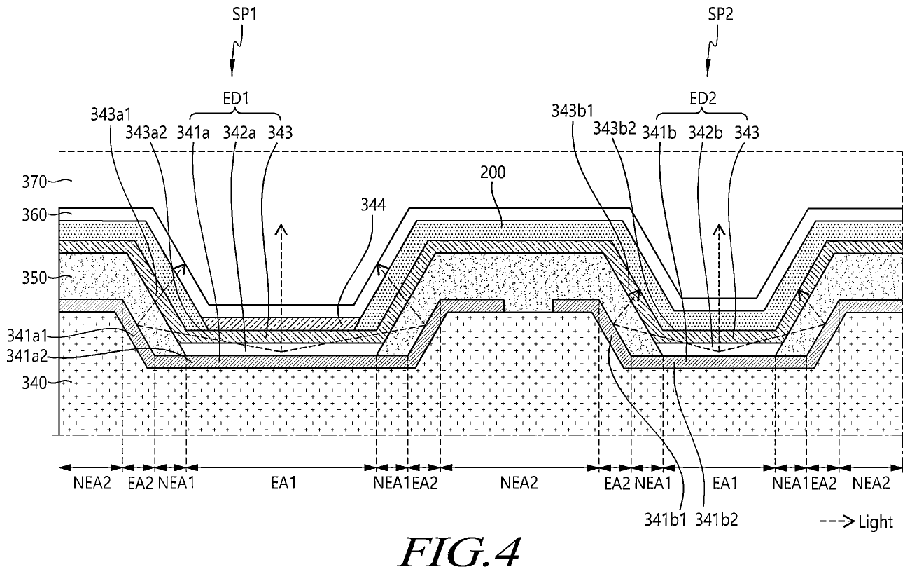

As illustrated in FIGS. 3 and 4, since the organic material layer 200 is disposed to cover the first inclined portion 343a1 of the first cathode electrode 343 and the organic material layer 200 is formed of a transparent material, light reflected from the inclined portion 341a1 of the first anode electrode 341a can be better extracted to the outside of the display device.

The organic material layer 200 can contact a side surface of the second cathode electrode 344. The organic material layer 200 can contact an upper surface of the first flat portion 343a2 of the first cathode electrode 343. In other words, the organic material layer 200 can be disposed between the second cathode electrode 344 and the first inclined portion 343a1 of the first cathode electrode 343. However, the disclosure is not necessarily limited thereto, and the organic material layer 200 can contact the upper surface of the second cathode electrode 344.

The organic material layer 200 can be disposed on the second flat portion 343b2 and the second inclined portion 343b1 of the first cathode electrode 343 in an area overlapping the second subpixel SP2. The organic material layer 200 can cover the entire upper surface of the first cathode electrode 343 disposed in the second subpixel SP2.

The second cathode electrode 344 can be disposed on the first flat portion 343a2 of the first cathode electrode 343 in an area overlapping the first subpixel SP1.

The second cathode electrode 344 can be formed in an area in which the organic material layer 200 is not disposed.

The second cathode electrode 344 can be formed after the organic material layer 200 is formed. Due to the difference in interfacial energy between the organic material layer 200 and the metal, the metal is not deposited on the organic material layer 200 but is mostly detached. Therefore, when the organic material layer 200 is first formed and then the second cathode electrode 344 is deposited, the second cathode electrode 344 is not formed on the organic material layer 200 but is formed only on an area in which the organic material layer 200 is not disposed.

In an embodiment, the thickness of the second cathode electrode 344 can be smaller than the thickness of the first cathode electrode 343. For example, the thickness of the first cathode electrode 343 can be 80 to 100 Å, and the thickness of the second cathode electrode 344 can be 20 Å to 60 Å. The sum of the thicknesses of the first cathode electrode 343 and the second cathode electrode 344 can be 120 Å to 140Å. However, the disclosure is not limited thereto.

A side surface of the second cathode electrode 344 can contact the first inclined portion 343a1 of the first cathode electrode 343. However, the disclosure is not necessarily limited thereto, and the side surface of the second cathode electrode 344 can contact the organic material layer 200. In other words, the second cathode electrode 344 can be spaced apart from the first inclined portion 343a1 of the first cathode electrode 343 with the organic material layer 200 interposed therebetween.

The first cathode electrode 343 and the second cathode electrode 344 can supply electrons to each of the light emitting layers 342a and 342b, can be formed of a conductive material having a low work function, and can be formed using a transparent conductive material that transmits light. For example, at least one of the first cathode electrode 343 and the second cathode electrode 344 can be formed of at least one or more of indium tin oxide (ITO) and indium zinc oxide (IZO), but is not limited thereto.

A capping layer 360 can be disposed on the organic material layer 200.

The capping layer 360 can protect the organic material layer 200 and can enhance the viewing angle of the display device by adjusting the refractive index.

The capping layer 360 can be formed of an organic material or an inorganic material, and can be formed of, e.g., a material such as lithium fluoride (LiF), but is not limited thereto.

An encapsulation layer 370 can be further disposed on the capping layer 360. The encapsulation layer 370 can serve to prevent moisture or oxygen from penetrating into the light emitting element ED, and can be disposed in the form of a thin film.

When the encapsulation layer 370 is in the form of a thin film, an organic encapsulation layer and an inorganic encapsulation layer can be alternately stacked.

For example, the encapsulation layer 370 can include a first encapsulation layer 371, a second encapsulation layer 372 disposed on the first encapsulation layer 371, and a third encapsulation layer 373 disposed on the second encapsulation layer 372. However, the disclosure is not limited thereto.

The first encapsulation layer 371 and the third encapsulation layer 373 can be inorganic encapsulation layers, and the second encapsulation layer 372 can be an organic encapsulation layer, but the disclosure is not limited thereto.

In various embodiments of the disclosure, one or more of the refractive indices of the first cathode electrode 343, the organic material layer 200, the second cathode electrode 344, the capping layer 360 and the encapsulation layer 370 can be adjusted to provide increased transmission of light.

A touch sensor layer for providing a touch function can be further disposed on the encapsulation layer 370. Further, a color filter layer can be disposed on the encapsulation layer 370 to increase color reproducibility. The color filter layer can be disposed between the encapsulation layer 370 and the touch sensor layer.

The touch sensor layer can include a first touch buffer layer 381, a second touch buffer layer 382, a touch electrode 383, and a bridge electrode 384.

The first touch buffer layer 381 can be disposed on the third encapsulation layer 373. The first touch buffer layer 381 can be formed as a single layer or multiple layers formed of any one of silicon oxide (SiOx) or silicon nitride (SiNx) or a combination thereof, but the disclosure is not limited thereto.

A second touch buffer layer 382 and a bridge electrode 384 can be disposed on the first touch buffer layer 381.

The second touch buffer layer 382 can be formed of the same material as the first touch buffer layer 381. But the disclosure is not limited thereto.

The bridge electrode 384 can connect the touch electrodes 320 to each other. The bridge electrode 384 can be disposed to overlap some or all of the touch electrodes 320 to connect the touch electrodes 320 to each other. Hereinafter, for convenience of description, a case in which the bridge electrode 384 is disposed to overlap all of the touch electrodes is described as an example.

A touch electrode 383 can be disposed on the bridge electrode 384. But the disclosure is not limited thereto.

The touch electrode 383 can be patterned in a mesh type as described above. But the disclosure is not limited thereto.

The touch electrode 383 and the bridge electrode 384 can be disposed in an area in which the second touch buffer layer 382 is open.

Touch electrode 383 and bridge electrode 384 can overlap each other. But the disclosure is not limited thereto.

The touch electrode 383 and the bridge electrode 384 can be positioned outside the inclined portion 341a1 of the first anode electrode 341a. In other words, the width of the opening area OA of the touch electrode 383 can be larger than the distance between the inclined portions 341a1 of the first anode electrode 341a positioned on two opposite sides of the flat portion 341a2 of the first anode electrode 341a.

FIG. 4 is an enlarged view of area A of FIG. 3.

Referring to FIG. 4, each subpixel SP1 and SP2 can include a first emission area EA1, a first non-emission area NEA1, and a second emission area EA2 as described above. A second non-emission area NEA2 can be positioned between the second emission area EA2 of the first subpixel SP1 and the second emission area EA2 of the second subpixel SP2.

The first emission area EA1 of the first subpixel SP1 can refer to an area in which the flat portion 341a2 of the first anode electrode 341a, the first light emitting layer 342a, and the first cathode electrode 343 are sequentially stacked. Alternatively, it can mean an opening area of the bank layer 350.

The first emission area EA1 of the second subpixel SP2 can refer to an area in which the flat portion 341b2 of the second anode electrode 341b, the second light emitting layer 342b, and the first cathode electrode 343 sequentially stacked. Alternatively, it can mean an opening area of the bank layer 350.

The area of the first emission area EA1 of the first subpixel SP1 can be larger than the area of the first emission area EA1 of the second subpixel SP2.

The first emission area EA1 of the first subpixel SP1 can overlap an area in which the second cathode electrode 344 is disposed.

The width of the second cathode electrode 344 can be equal to the width of the first emission area EA1. However, the disclosure is not limited thereto.

The first non-emission area NEA1 of each subpixel SP1 and SP2 can surround the first emission area EA1.

The first non-emission area NEA1 can be an area that does not overlap the first light emitting layer 342a in an area in which the flat portion 341a2 of the first anode electrode 341a is disposed and an area that does not overlap the second light emitting layer 342b in an area in which the flat portion 341b2 of the second anode electrode 341b is disposed.

The second emission area EA2 of each subpixel SP1 and SP2 can surround the first non-emission area NEA1.

The second emission area EA2 is an emission area that can be formed by the light reflected by the inclined portion 341a1 of the first anode electrode 341a or the inclined portion 341b1 of the second anode electrode 341b of the light emitted from the first light emitting layer 342a or the second light emitting layer 342b, and is an emission area formed in an area other than the first emission area EA1.

The second emission area EA2 can be an area in which the inclined portion 341a1 of the first anode electrode 341a is disposed or an area in which the inclined portion 341b1 of the second anode electrode 341b is disposed.

The second non-emission area NEA2 can surround the second emission area EA2. The second non-emission area NEA2 can be an area between the second emission area EA2 of the first subpixel SP1 and the second emission area EA2 of the second subpixel SP2.

The organic material layer 200 can overlap the first emission area EA1, the first non-emission area NEA1, and the second non-emission area NEA2 of the second subpixel SP2.

The organic material layer 200 can overlap the second emission area EA2 and the first non-emission area NEA1 of the first subpixel SP1.

In other words, the organic material layer 200 can be disposed in an area other than the first emission area EA1 of the first subpixel SP1 in the area in which the plurality of subpixels SP are disposed.

In the display device described with reference to FIGS. 2 to 4, the organic material layer 200 can be disposed in an area other than the first emission area EA1 of the first subpixel SP1 in the area in which the plurality of subpixels SP are disposed, and the second cathode electrode 344 can be disposed in the first emission area EA1 of the first subpixel SP1.

Here, the area of the first emission area EA1 of the first subpixel SP1 can be larger than the area of the first emission area EA1 of the second subpixel SP2 as described above.

In other words, in the case of a subpixel having a relatively large area of the first emission area EA1, the cathode electrode can be formed to be thick by stacking double cathode electrodes, and in the case of a subpixel having a relatively small area of the first emission area EA1, the cathode electrode can be formed to be thin by having the cathode electrode in one layer.

Meanwhile, as the thickness of the cathode electrode decreases, the amount of light reflected by the cathode electrode of the light emitted from the light emitting layer decreases. Accordingly, since the amount of light returning into the light emitting layer is reduced, light efficiency for extracting the light to the outside of the light emitting element using resonance (micro-cavity) can be reduced.

On the other hand, as the thickness of the cathode electrode increases, the path through which light emitted from the light emitting layer can travel is limited, and thus the viewing angle characteristic can be deteriorated, such as a decrease in the viewing angle of the display device or a decrease in the viewing angle luminance.

As illustrated in FIGS. 2 to 4, when the cathode electrode of the subpixel having a relatively large area of the first emission area EA1 is formed to be thick, the amount of light reflected by the cathode electrode of the light emitted from the light emitting layer increases, and thus the light efficiency of extracting light to the outside using resonance can increase. When the cathode electrodes of the subpixels other than the subpixels having a relatively large area of the first emission area EA1 is formed to be thin, the path through which the light emitted from the light emitting layer can spread is relatively wide, and thus the viewing angle characteristic can be prevented from deteriorating.

Described with reference to FIGS. 2 to 4 is an example of a display device in which the cathode electrode included in the blue subpixel has a larger thickness, and the cathode electrode included in the red or green subpixel has a smaller thickness. However, without limitations thereto, the cathode electrode included in any one of the red, green, and blue subpixels can be formed to be thick, and the cathode electrode included in another subpixel can be formed to be thin.

In other words, it is possible to enhance the light efficiency of the display device while preventing deterioration of the viewing angle characteristics by forming the cathode electrode in a different thickness for each subpixel.

Hereinafter, another structure of a display device capable of preventing deterioration of the viewing angle characteristics while enhancing light efficiency is described.

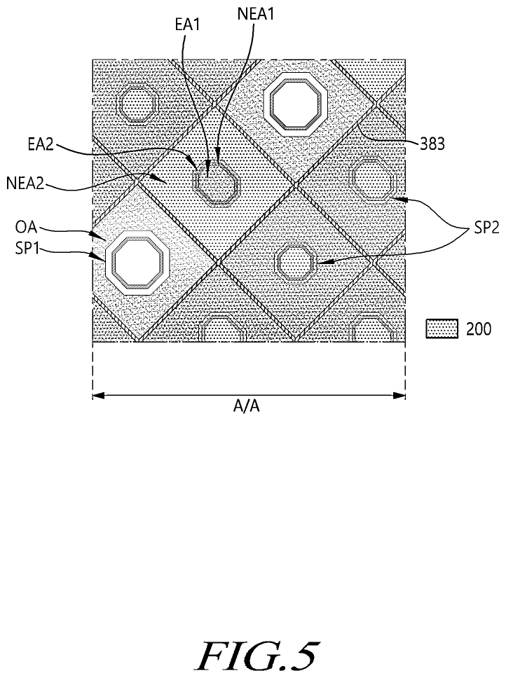

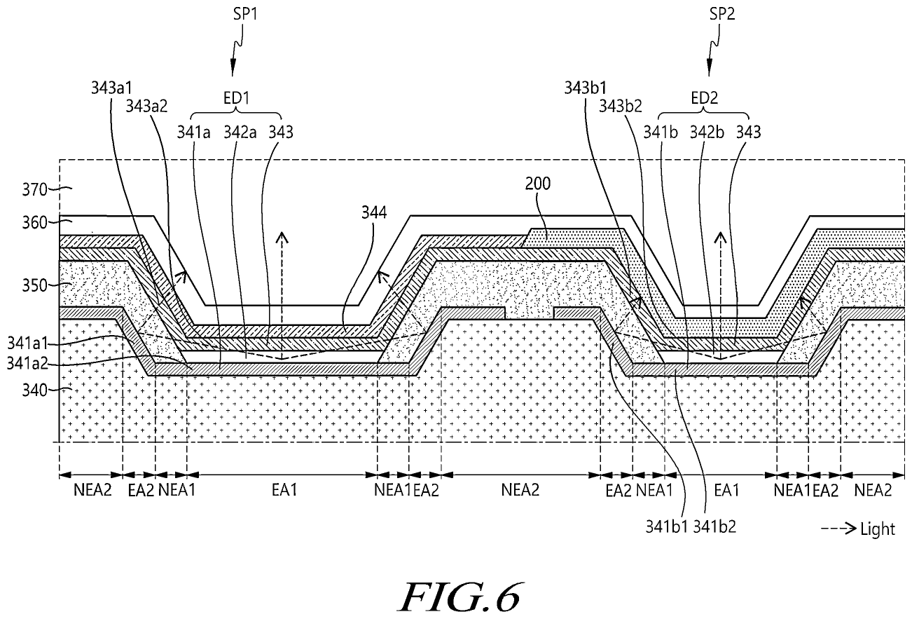

FIG. 5 is a view illustrating another example of a planar structure of a display device according to embodiments of the disclosure. FIG. 6 is a view illustrating another example of a cross-sectional structure of the display device of FIG. 4.

The planar structure of the display device illustrated in FIGS. 5 and 6 is the same as the planar structure of the display device described with reference to FIG. 2 except that the area in which the first cathode electrode 343 is disposed becomes larger and the area in which the organic material layer 200 is disposed becomes smaller, and thus no duplicate description is given below.

Referring to FIG. 5, as described above, a plurality of first subpixels SP1 and a plurality of second subpixels SP2 can be alternately disposed in the display area A/A.

The area of the first emission area EA1 of the first subpixel SP1 can be larger than the area of the first emission area EA1 of the second subpixel SP2.

The organic material layer 200 can be disposed to overlap at least one subpixel SP.

For example, as illustrated in FIG. 5, the organic material layer 200 can overlap all of the first emission area EA1, the first non-emission area NEA1, and the second emission area EA2 of the second subpixel SP2. However, the disclosure is not limited thereto.

Further, the organic material layer 200 can overlap at least a portion of the second non-emission area NEA2.

The organic material layer 200 can be not overlapping the first emission area EA1, the first non-emission area NEA1, and the second emission area EA2 of the first subpixel SP1. Further, the organic material layer 200 can be not overlapping the second non-emission area NEA2 adjacent to the second emission area EA2 of the first subpixel SP1.

A second cathode electrode can be disposed in an area in which the organic material layer 200 is not disposed in the second non-emission area NEA2 adjacent to the second emission area EA2 of the first subpixel SP1.

Referring to FIG. 6, the organic material layer 200 and the second cathode electrode 344 can be disposed on the first cathode electrode 343.

The organic material layer 200 can overlap the second subpixel SP2 and can be partially open in the area overlapping the first subpixel SP1.

The organic material layer 200 can overlap the first emission area EA1, the first non-emission area NEA1, and the second emission area EA2 of the second subpixel SP2, and can partially overlap the second non-emission area NEA2 between the first subpixel SP1 and the second subpixel SP2.

The second cathode electrode 344 can be disposed on the first flat portion 343a2 and the first inclined portion 343a1 of the first cathode electrode 343 in the area overlapping the first subpixel SP1.

The second cathode electrode 344 can overlap the first emission area EA1, the first non-emission area NEA1, and the second emission area EA2 of the first subpixel SP1, and can also partially overlap the second non-emission area NEA2 between the first subpixel SP1 and the second subpixel SP2.

Both the second cathode electrode 344 and the organic material layer 200 can be disposed in the second non-emission area NEA2 between the first subpixel SP1 and the second subpixel SP2.

The second cathode electrode 344 and the organic material layer 200 can contact each other in the second non-emission area NEA2 between the first subpixel SP1 and the second subpixel SP2.

Here, the thickness of the organic material layer 200 can be larger than the thickness of the second cathode electrode 344. But the disclosure is not limited thereto.

The organic material layer 200 can also be disposed in the second non-emission area NEA2 between the second subpixel SP2 and another second subpixel SP2.

In the display device illustrated in FIGS. 5 and 6, since the thickness of the cathode electrode of the first subpixel SP1 is larger and the thickness of the cathode electrode of the second subpixel SP2 is smaller, the thickness of the cathode electrode differs for each subpixel, thereby enhancing the light efficiency of the display device and preventing deterioration of the viewing angle characteristics.

Further, when the organic material layer 200 is disposed as illustrated in FIG. 5, it is not necessary to finely adjust the range of the opening area of the organic material layer 200 to limit the area in which the second cathode electrode 344 is disposed, making it easy to design a mask for depositing the organic material layer 200.

The arrangement structure of the cathode electrode in the display area described above with reference to FIGS. 2 to 6 can be applied to various display devices. Hereinafter, such an example is described.

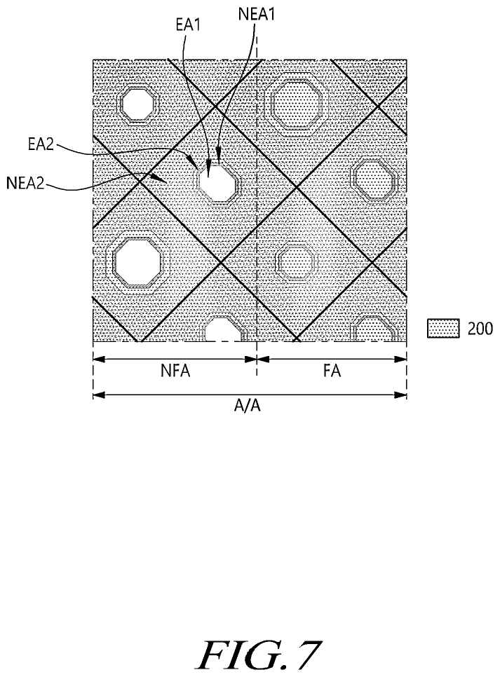

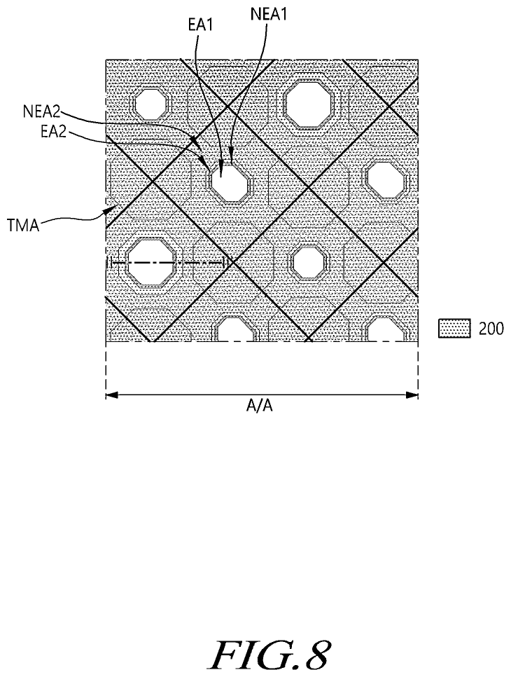

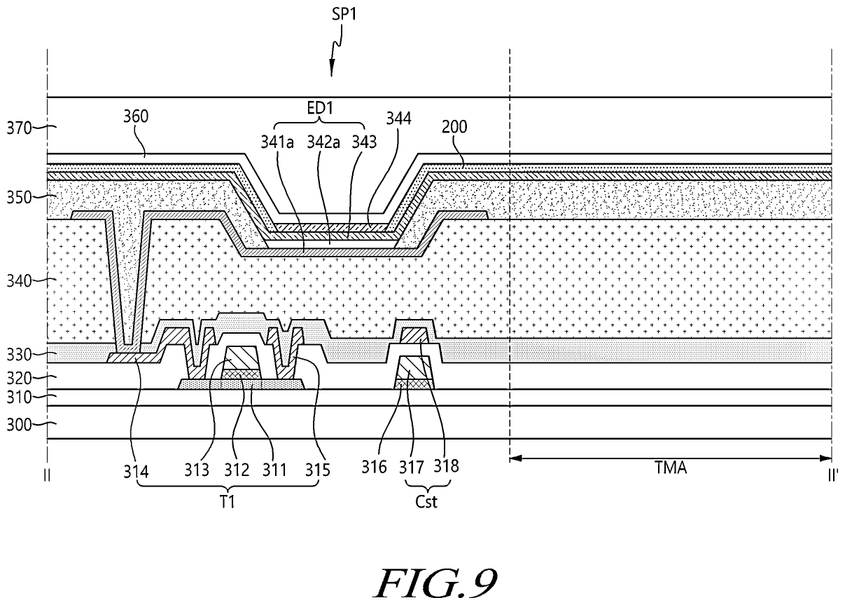

FIGS. 7 and 8 are views illustrating another example of a planar structure of a display device according to embodiments of the disclosure. FIG. 9 is a view illustrating an example of a cross-sectional structure of part II-II′ of FIG. 8.

Referring to FIG. 7, a display device providing a bending function can include a folding area FA and a non-folding area NFA in the display area A/A.

The folding area FA refers to an area in which at least a portion of the display device can be bent. The non-folding area NFA refers to an area in which the display device is not bent and can also be referred to as a flat area.

The organic material layer 200 can be disposed in a portion of the folding area FA and the non-folding area NFA.

Each subpixel SP disposed in the folding area FA can overlap the organic material layer 200.

The first cathode electrode can be disposed under the organic material layer 200 and can be disposed throughout the display area A/A.

Each of the subpixels SP disposed in the non-folding area NFA can partially overlap the organic material layer 200.

The organic material layer 200 can be disposed in an area other than the first emission area EA of each subpixel SP in the non-folding area NFA.

In a similar manner as illustrated in FIGS. 2 to 4, the second cathode electrode can be disposed in an area in which the organic material layer 200 is not disposed in the non-folding area NFA, i.e., an area overlapping the first emission area EA1 of each subpixel SP.

The second cathode electrode can be disposed on the first cathode electrode in the area overlapping the first emission area EA1.

As described above, in the non-folding area NFA, the first cathode electrode and the second cathode electrode are disposed in each of the subpixels SP, and in the folding area FA, the first cathode electrode is disposed in each of the subpixels SP, so that the thickness of the cathode electrode of the subpixel SP included in the folding area FA can be smaller than the thickness of the cathode electrode of the subpixel SP included in the non-folding area NFA.

Therefore, it is possible to increase light efficiency in the non-folding area NFA while simultaneously preventing deterioration of the viewing angle characteristics that can occur when the display device is bent in the folding area FA.

Referring to FIGS. 8 and 9, the display device can include at least one transmissive area TMA.

The planar and cross-sectional structures of the display device illustrated in FIGS. 8 and 9 are the same as the planar and cross-sectional structures of the display device described with reference to FIGS. 2 and 3 except that the display device includes the transmissive area TMA, and thus no duplicate description is given.

The transmissive area TMA can be defined as an area having higher transparency than the surrounding area, such as one or more of the subpixels SP.

The transmissive area TMA can be disposed in the display area of the display panel to be used to increase the transmittance of the display panel, or can be disposed on a sensor recognizing an object to be used to provide a path through which light passes, but is not limited thereto.

The transmissive area TMA can be formed between a plurality of subpixels SP disposed in the display area A/A.

As illustrated in FIG. 8, the transmissive area TMA can have an octagonal shape. However, the disclosure is not limited thereto, and the transmissive area TMA can have a circular shape, an elliptical shape, or a polygonal shape (e.g., a triangle, a square, or a hexagon) on a plane, or can be formed of a combination thereof.

The transmissive area TMA can overlap the second non-emission area NEA2.

The transmissive area TMA can be an area having higher transparency than the other area of the second non-emission area NEA2.

The organic material layer 200 can be disposed to overlap a plurality of subpixels SP including the transmissive area TMA.

Specifically, the organic material layer 200 can be disposed in an area other than the first emission area EA1 of the plurality of subpixels SP.

In other words, the organic material layer 200 can overlap the first non-emission area NEA1 and the second emission area EA2 of the plurality of subpixels SP, and can overlap the second non-emission area NEA2 between the plurality of subpixels SP.

Referring to FIG. 9, the second cathode electrode 344 and the organic material layer 200 can be disposed on the first cathode electrode 343.

The organic material layer 200 can be disposed on the first cathode electrode 343 in the transmissive area TMA, and can be partially disposed to overlap the subpixel.

The organic material layer 200 can contact a side surface of the second cathode electrode 344. The organic material layer 200 can contact an upper surface of the first cathode electrode 343. In other words, the organic material layer 200 can be disposed between the inclined surfaces of the second cathode electrode 344 and the first cathode electrode 343. However, the disclosure is not necessarily limited thereto, and the organic material layer 200 can contact the upper surface of the second cathode electrode 344 in an area overlapping the subpixel.

The second cathode electrode 344 can be disposed on the first cathode electrode 343 in an area in which the organic material layer 200 is not disposed in the area overlapping the subpixel.

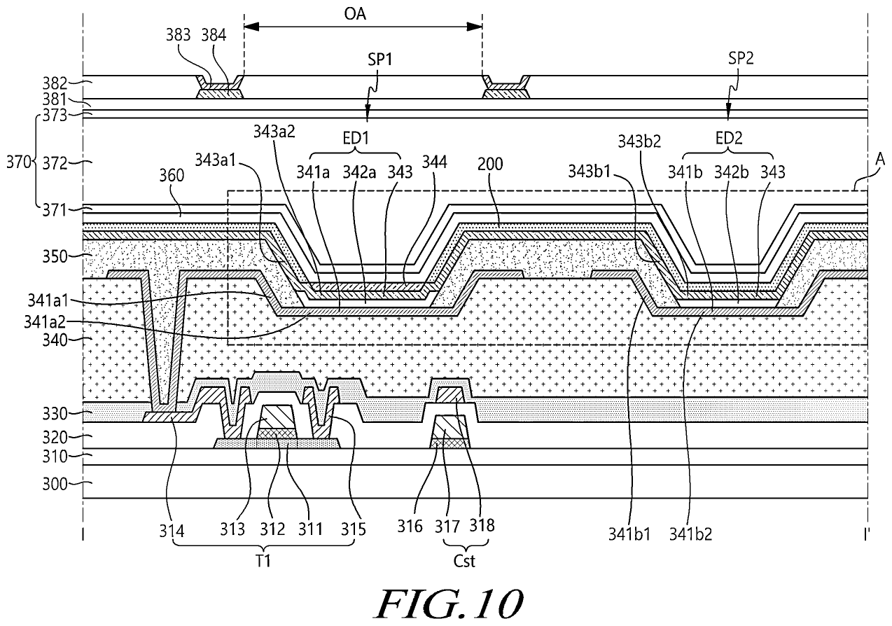

FIG. 10 is an enlarged view of area A of FIG. 3 according to another embodiment of the disclosure.

The cross-sectional structures of the display device illustrated in FIG. 10 are the same as the cross-sectional structures of the display device described with reference to FIG. 3 except that the first light emitting layer 342a of the first subpixel SP1 is disposed on the flat portion 341a2 of the first anode electrode 341a and on a surface of the bank layer 350, and thus no duplicate description is given.

With reference to FIG. 10, the first light emitting layer 342a of the first subpixel SP1 can be disposed on the flat portion 341a2 of the first anode electrode 341a and a portion of the first light emitting layer 342a can be disposed on the surface of the bank layer 350. Accordingly, the first light emitting layer 342a can be included in the first emission area EA1 and a portion of the first non-emission areas NEA1, and the portion of the first light emitting layer 342a can be parallel to a portion of the inclined portion 341a of the first anode electrode 341a. In this regard, a lowermost portion of the bank layer 350 can come into contact with a surface of the first light emitting layer 342a and can be disposed between an inclined portion 341a1 of the first anode electrode 341a and an inclined portion of the first light emitting layer 342a.

As provided in FIG. 10, for example, a portion of the bank layer 350 that is inclined can be interposed between the inclined portions 341a1 of the first anode electrode 341a and the first inclined portion 343a1 of the first cathode electrode 343 to maintain a first distance between the inclined portions 341a1 of the first anode electrode 341a and the first inclined portion 343a1 of the first cathode electrode 343. Also, the first light emitting layer 342a can have an inclined portion that can be interposed between the inclined portion of the bank layer 350 and an inclined portion of the first cathode electrode 343. Also, the first light emitting layer 342a can have a flat portion that can be interposed between the flat portion 341a2 of the first anode electrode 341a and a flat portion of the first cathode electrode 343 to maintain a second distance therebetween. In this regard, the first distance can be different from the second distance. In various embodiments, the first distance can be greater than the second distance. However, the disclosure is not limited thereto.

With reference to FIG. 10, a first thickness of the portion of the bank layer 350 interposed between the inclined portions 341a1 of the first anode electrode 341a and the first inclined portion 343a1 of the first cathode electrode 343 can be different from a second thickness of the first light emitting layer 342a. For example, the first thickness can be greater than the second thickness, but the disclosure is not limited thereto. For example, the first thickness can be equal to or less than the second thickness.

In various embodiments, the first thickness of the inclined portion of the bank layer 350 interposed between the inclined portions 341a1 of the first anode electrode 341a and the first inclined portion 343a1 of the first cathode electrode 343 can vary, whereby the thickness of the inclined portion of the bank layer 350 adjacent the first light emitting layer 342a can be less than the thickness of the inclined portion of the bank layer 350 at the opposite end (near the flat portion of the bank layer 350).

With reference to FIG. 10, a thickness of the first light emitting layer 342a is depicted as constant in the first emission area EA1 and the first non-emission area NEA1, but the disclosure is not limited thereto. For example, the thickness of the first light emitting layer 342a in a first emission area EA1 can be different from the thickness of the first light emitting layer 342a in the first non-emission area NEA1. Also, the thickness of the first light emitting layer 342a in the first non-emission area NEA1 can be greater than or less than that the thickness of the first light emitting layer 342a in a first emission area EA1.

Additionally, with reference to FIG. 10, the inclined portion of the first light emitting layer 342a in the first non-emission area NEA1 is separated from the first inclined portion 343a1 of the first anode electrode 341a so that the inclined portion of the bank layer 350 can extend to contact the inclined portion of the first light emitting layer 342a.

With reference to FIG. 10, the first inclined portion 343a1 of the first cathode electrode 343 can be disposed on the inclined portion of the bank layer 350 and continue to extend to be disposed on the inclined portion of the first light emitting layer 342a. As the first inclined portion 343a1 of the first cathode electrode 343 extends from the inclined portion of the bank layer 350 to the inclined portion of the first light emitting layer 342a, the first inclined portion 343a1 of the first cathode electrode 343 can include a step structure. In various embodiments of the disclosure, an edge or an end of the organic material layer 200 that is disposed on the inclined portion of the bank layer 350 can be on the step structure of the first inclined portion 343a1 of the first cathode electrode 343.

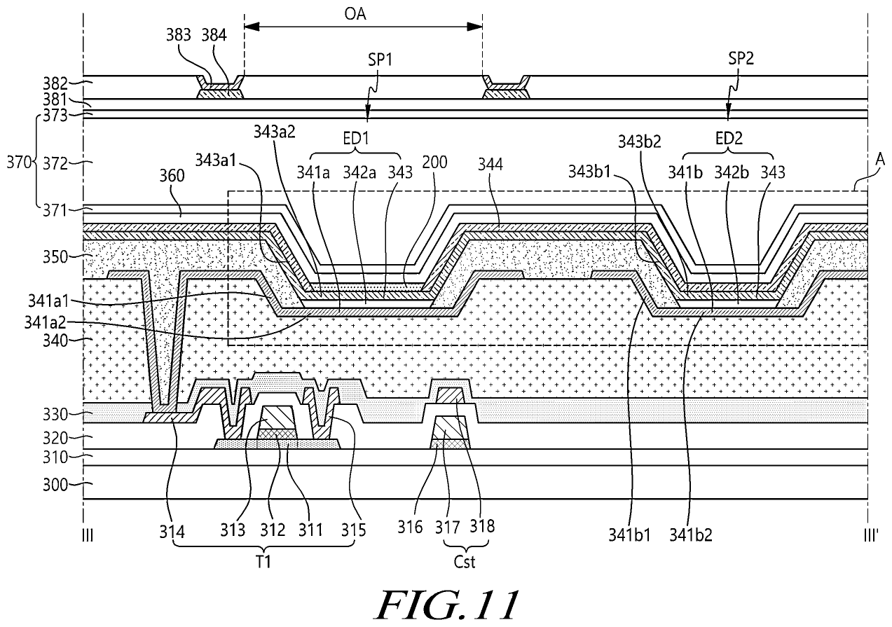

FIG. 11 is an enlarged view of area A of FIG. 3 according to another embodiment of the disclosure.

The cross-sectional structures of the display device illustrated in FIG. 11 is similar as the cross-sectional structures of the display device described with reference to FIG. 3 except that locations of the organic material layer 200 and the second cathode electrode 344 are switched, and thus no duplicate description is given.

With reference to FIG. 11, the organic material layer 200 and the second cathode electrode 344 can be disposed on the first cathode electrode 343. For example, the organic material layer 200 can overlap the first subpixel SP1, and the second cathode electrode 344 can partially overlap the first subpixel SP1, and can overlap the second subpixel SP2. Specifically, the organic material layer 200 can be disposed to overlap the first emission area EA1 of the first subpixel SP1 and not overlap the first emission area EA1 of the second subpixel SP2. Meanwhile, the second cathode electrode 344 can be disposed to not overlap the first emission area EA1 of the first subpixel SP1, but can overlap a first non-emission area NEA1 of the first subpixel SP1, a second emission area EA2 of the first subpixel SP1, a second non-emission area NEA2 of the first subpixel SP1, a second non-emission area NEA2 of the second subpixel SP2, a second emission area EA2 of the second subpixel SP2, a first non-emission area NEA1 of the second subpixel SP2 and a first emission area EA1 of the second subpixel SP2.

With reference to FIG. 11, the second cathode electrode 344 can extend from the second non-emission area NEA2 to the first non-emission area NEA1 in the first subpixel SP1, and can extend from the second non-emission area NEA2 to the first emission area EA1 in the second subpixel SP2, but embodiments of the disclosure are not limited thereto. Also, a capping layer 360 can be disposed on the second cathode electrode 344 and the organic material layer 200 in the first subpixel SP1, and the capping layer 360 can extend from the second non-emission area NEA2 to the first emission area EA1 in the first subpixel SP1 and the second subpixel SP2.

With reference to FIG. 11, the bank layer 350 can include an open area, where the open area of the bank layer 350 corresponds to a portion of the first emission area EA1 of the first subpixel SP1. The organic material layer 200 can be disposed in the open area of the bank layer 350. Also, the second cathode electrode 344 can include an open area, wherein the open area of the second cathode electrode 344 can correspond to a portion of the first emission area EA1, and the organic material layer is in the open area.

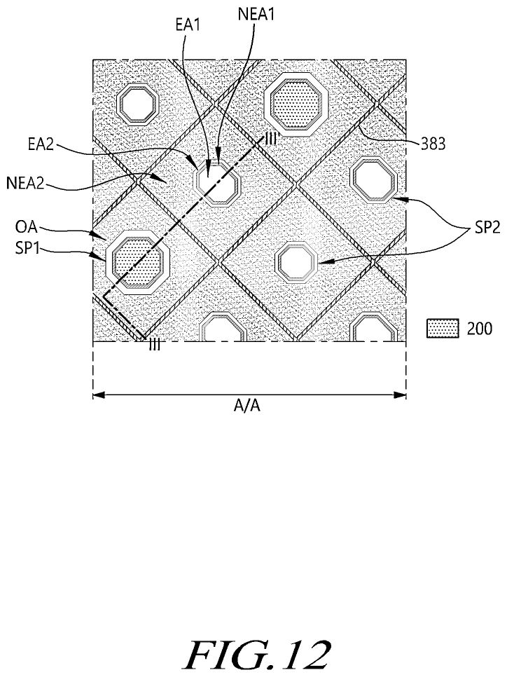

FIG. 12 is a view illustrating an example of a planar structure of a display device according to embodiments of the disclosure. The planar structure of the display device illustrated in FIG. 12 is similar to the planar structure of the display device described with reference to FIG. 2 except that an area in which the organic material layer 200 is disposed on the first emission area EA1 of the first subpixel SP1, and the organic material layer 200 is not disposed on the first emission area EA1 of the second subpixel SP2, and thus no duplicate description is given below.

With reference to FIG. 12, the second cathode electrode 344 can overlap the first emission area EA1, the first non-emission area NEA1, the second emission area EA2 and the second non-emission area of the second subpixel SP2, and can also overlap the second non-emission area NEA2 between the first subpixel SP1 and the second subpixel SP2. The second cathode electrode 344 can overlap the first non-emission area NEA1, the second emission area EA2 and the second non-emission area of the first subpixel SP1, but embodiments of the disclosure are not limited thereto.

In various embodiments of the disclosure, the second subpixel SP2 can include a similar structure as those of the first subpixel SP1 regarding the first light emitting layer 342a of the first subpixel SP1 being disposed on the entire flat portion 341a2 of the first anode electrode 341a.

As described above, using the organic material layer 200, the second cathode electrode 344 can be selectively disposed only in an area in which subpixels are disposed in the area in which the first cathode electrode 343 is disposed. Further, the organic material layer 200 can be formed of a transparent material.

In other words, it is possible to enhance the light efficiency of the display device by increasing the thickness of the cathode electrode in the area overlapping the area in which the subpixels are disposed, and it is possible to ensure transparency of the display device by decreasing the thickness of the cathode electrode in the transmissive area TMA.

Embodiments of the disclosure described above are briefly described below.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed is:

1. A display panel comprising:
a substrate including a plurality of data lines, a plurality of gate lines, and a plurality of subpixels arranged in a display area of the display panel;
a planarization layer on the plurality of data lines, the plurality of gate lines, and the plurality of subpixels,
wherein each subpixel includes:
an anode electrode, a light emitting layer, and a cathode electrode that are sequentially stacked,
one of an auxiliary cathode electrode and an organic material layer on the cathode electrode, and
a capping layer on the one of the auxiliary cathode electrode and the organic material layer on the cathode electrode.

2. The display panel of claim 1, wherein each subpixel includes:
a first emission area corresponding to the anode electrode, the light emitting layer, and the cathode electrode that are stacked;
a first non-emission area encircling the first emission area; and
a second emission area encircling the first non-emission area, and
wherein the first non-emission area is interposed between the first emission area and the second emission area.

3. The display panel of claim 1, wherein the first non-emission area has a lower luminance that those of the first emission area and the second emission area.

4. The display panel of claim 1, wherein the auxiliary cathode electrode and the organic material layer are transparent.

5. The display panel of claim 4, wherein the auxiliary cathode electrode includes at least one of indium tin oxide (ITO) and indium zinc oxide (IZO).

6. The display panel of claim 1, wherein the plurality of subpixels include a first subpixel and a second subpixel,
wherein the first subpixel includes the auxiliary cathode electrode on the cathode electrode, and the second subpixel includes the organic material layer on the cathode electrode, and
wherein a thickness of the auxiliary cathode electrode is different from a thickness of the organic material layer.

7. The display panel of claim 6, wherein the first subpixel includes the auxiliary cathode electrode on a flat portion of the cathode electrode, and the organic material layer on an inclined portion of the cathode electrode.

8. The display panel of claim 6, wherein the first subpixel includes the auxiliary cathode electrode on a flat portion and an inclined portion of the cathode electrode.

9. The display panel of claim 6, wherein the cathode electrode extends from the first subpixel to the second subpixel.

10. The display panel of claim 6, wherein the light emitting layer of the first subpixel emits a blue light, and
wherein the light emitting layer of the second subpixel emits a blue light or a green light.

11. The display panel of claim 6, wherein a first emission area of the first subpixel is larger than a first emission area of the second subpixel.

12. The display panel of claim 1, wherein the plurality of subpixels include a first subpixel and a second subpixel, and
wherein the first subpixel and the second subpixel include the auxiliary cathode electrode on the cathode electrode.

13. The display panel of claim 12, wherein the organic material layer is on inclined portions of the cathode electrode in the first subpixel and the second subpixel.

14. The display panel of claim 12, further comprising a transmissive area disposed adjacent to the first subpixel and the second subpixel,
wherein the transmissive area has a higher transparency than the first subpixel and the second subpixel.

15. The display panel of claim 14, wherein the organic material layer is on the transmissive area.

16. A display device comprising:
the display panel of claim 1; and
an encapsulation layer on the display panel.

17. A display panel comprising:
a first subpixel and a second subpixel on a substrate;
a planarization layer on the first and second subpixels; and
a bank layer on the planarization layer,
wherein each of the first and second subpixels includes an anode electrode, a light emitting layer, and a cathode electrode that are sequentially stacked,
wherein the first subpixel includes an auxiliary cathode electrode on the cathode electrode of the first subpixel, and the second subpixel includes an organic material layer on the cathode electrode of the second subpixel, and
wherein a thickness of the auxiliary cathode electrode is different from a thickness of the organic material layer.

18. The display panel of claim 17, wherein, for the first subpixel, the anode electrode includes a flat portion parallel to the substrate and an inclined portion angled to the substrate,
wherein, for the first subpixel, the cathode electrode includes a flat portion parallel to the substrate and an inclined portion angled to the substrate, and
wherein the light emitting layer is on the flat portion of the anode electrode, and
wherein the auxiliary cathode electrode is on the flat portion of the cathode electrode.

19. The display panel of claim 17, wherein the first subpixel includes:
a first emission area corresponding to the light emitting layer,
a first non-emission area encircling the first emission area; and
a second emission area encircling the first non-emission area, and
wherein the first non-emission area is interposed between the first emission area and the second emission area.

20. The display panel of claim 17, wherein the light emitting layer is on the flat portion of the anode electrode entirely, and extends on the inclined portion of the bank layer.

21. A display panel comprising:
a substrate including a plurality of subpixels arranged in a display area of the display panel; and
a planarization layer on the substrate,
wherein each subpixel includes:
a first emission area, a second emission area surrounding the first emission area, a first non-emission area between the first emission area and the second emission area, and a second non-emission area surrounding the second emission area, and
wherein each subpixel further includes:
an anode electrode extending from the second non-emission area to the first emission area,
a light emission layer on the anode electrode and overlapping the first emission area,
a cathode electrode on the light emission layer and extending from the second non-emission area to the first emission area,
an organic layer on the cathode electrode and overlapping the first emission area, and
an auxiliary cathode electrode on the cathode electrode and extending from the second non-emission area to the first non-emission area.

22. The display panel of claim 21, further comprising:
a capping layer on the auxiliary cathode electrode and the organic layer, and extending from the second non-emission area to the first emission area.

23. The display panel of claim 21, wherein the bank layer includes an open area, and the organic layer is in the open area.

24. The display panel of claim 21, wherein the auxiliary cathode electrode includes an open area, and the organic layer is in the open area.
